(19) United States
(12) Patent Application Publication
(10) Pub. No.: US 2017/0084458 A1
(43) Pub. Date: Mar. 23, 2017

(54) METHOD OF FABRICATING CRYSTALLINE INDIUM-GALLIUM-ZINC OXIDE SEMICONDUCTOR LAYER AND THIN FILM TRANSISTOR

(71) Applicant: AU OPTRONICS CORPORATION, Hsin-chu (TW)

(72) Inventor: Jia-Hong YE, Hsin-chu (TW)

(21) Appl. No.: 15/254,201

(22) Filed: Sep. 1, 2016

(30) Foreign Application Priority Data
Sep. 21, 2015 (TW) 104131145

(51) Int. Cl. H01L 21/02; H01L 29/24; H01L 29/786; H01L 29/66

(52) U.S. Cl. CPC H01L 21/02694; H01L 21/02565; H01L 21/02631; H01L 29/66969; H01L 29/24; H01L 29/7869; H01L 29/78696

(57) ABSTRACT

A method of fabricating a crystalline IGZO semiconductor layer including a following step is provided. An IGZO sputter target is bombarded with plasma-generated ions in a condition of a process temperature higher than 200° C., an O₂ flow greater than 60 sccm and an Ar flow less than 20 sccm so as to form a crystalline IGZO semiconductor layer on a substrate. Moreover, a method of fabricating a thin film transistor having the crystalline IGZO semiconductor layer is also provided.

### TECHNICAL FIELD

The present disclosure relates to a method of fabricating a semiconductor layer and a semiconductor component; in particular, to a method of fabricating a crystalline indium-gallium-zinc oxide semiconductor layer and a thin film transistor.

### BACKGROUND ART

Recently, with the rise of environmental awareness, flat display panels with low power consumption, good space utilization efficiency, radiation-free, high-resolution, and other superior characteristics have become the market mainstream. Common flat panel displays include liquid crystal displays, plasma displays, organic electroluminescent displays, and the like.

Take liquid crystal displays, which are the most popular, for example. A liquid crystal display is mainly composed of a pixel array substrate, a color filter substrate, and a liquid crystal layer sandwiched therebetween. On the conventional pixel array substrate, a thin film transistor is often used as a switching component for each pixel structure, and the performance of the switching component often depends on how good or bad the quality of a channel layer of the thin film transistor is. The channel layer of a thin film transistor (such as a metal-oxide semiconductor) is prone to be damaged during the process of patterning a source and a drain or by the ambient moisture, which is disadvantageous to the quality of the thin film transistor. To overcome this problem, in the conventional method of fabricating a thin film transistor, an etch stop layer is first formed on the channel layer of the thin film transistor, the conductive layer over the etch stop layer is then patterned to form the source and the drain of the thin film transistor. Thereby, either by a wet etching process or a dry etching process for pattering as to form the source and the drain, the channel layer of the thin film transistor is not prone to be damaged by the etching solution in the wet etching process or by the plasma in the dry etching process. In addition, since the etch stop layer covers the area of at least a portion of the channel layer, the chance for the channel to be in contact with the moisture is reduced, thereby reducing the chance of amorphous channel layer deteriorated to become conductive due to the influence of the moisture. However, disposing of the etch stop layer has caused the issues of a decrease in opening ratio of the pixel array substrate, an increase in fabrication cost of the thin film transistor, and the like.

### SUMMARY

The present disclosure is to provide a method of fabricating a crystalline indium-gallium-zinc oxide semiconductor layer, and the crystalline indium-gallium-zinc oxide semiconductor layer fabricated by the same has resistance to etching solutions.

The present disclosure is to provide a method of fabricating a thin film transistor, and the thin film transistor fabricated by the same provides good performance at lower cost.

A method of fabricating a crystalline indium-gallium-zinc oxide semiconductor layer of the present disclosure includes the following step(s). An indium-gallium-zinc oxide sputter target is bombarded with plasma-generated ions in a condition of a process temperature higher than 200 Celsius degrees, an oxygen gas flow greater than 60 sccm, and an argon gas flow less than 20 sccm, so as to form a crystalline indium-gallium-zinc oxide semiconductor layer on a substrate.

A method of fabricating a thin film transistor of the present disclosure includes the following step(s). A gate electrode, a source electrode, a drain electrode, and a crystalline indium-gallium-zinc oxide semiconductor layer are formed on a substrate, where the crystalline indium-gallium-zinc oxide semiconductor layer is formed by bombarding an indium-gallium-zinc oxide sputter target with plasma-generated ions in a condition of a process temperature higher than 200 Celsius degrees, an oxygen gas flow greater than 60 sccm, and an argon gas flow less than 20 sccm.

A thin film transistor of the present disclosure is fabricated by the above-mentioned method of fabricating a thin film transistor. The thin film transistor includes a gate electrode, a crystalline indium-gallium-zinc oxide semiconductor layer (i.e. channel layer), a source electrode, and a drain electrode, the crystalline indium-gallium-zinc oxide semiconductor layer overlaps the gate electrode, and the source electrode and the drain electrode are electrically connected to two ends of the crystalline indium-gallium-zinc oxide semiconductor layer.

In an embodiment of the present disclosure, the method of fabricating a crystalline indium-gallium-zinc oxide semiconductor layer further includes the substrate is heated to over 200 Celsius degrees before the indium-gallium-zinc oxide sputter target is bombarded with the plasma-generated ions.

In an embodiment of the present disclosure, the process temperature is from 200 to 270 Celsius degrees while bombarding the indium-gallium-zinc oxide sputter target with the plasma-generated ions.

In an embodiment of the present disclosure, the argon gas flow is less than 5 sccm and the oxygen gas flow is less than 100 sccm while bombarding the indium-gallium-zinc oxide sputter target with the plasma-generated ions.

In an embodiment of the present disclosure, the method of fabricating a crystalline indium-gallium-zinc oxide semiconductor layer further includes a matrix at least including the substrate is cleaned before the indium-gallium-zinc oxide sputter target is bombarded with the plasma-generated ions.

Accordingly, in a method of fabricating a crystalline indium-gallium-zinc oxide semiconductor layer of an embodiment of the present disclosure, a crystalline indium-gallium-zinc oxide semiconductor layer is formed by bombarding an indium-gallium-zinc oxide sputter target with plasma-generated ions in a condition of a process temperature higher than 200 Celsius degrees, an oxygen gas flow greater than 60 sccm, and an argon gas flow less than 20 sccm. Thereby, the crystalline indium-gallium-zinc oxide semiconductor layer can have a good crystallization quality and have resistance to etching solutions.

In a method of fabricating a thin film transistor of an embodiment of the present disclosure, a channel layer of a fabricated thin film transistor is formed by patterning an above-mentioned crystalline indium-gallium-zinc oxide semiconductor layer. Therefore, the channel layer also has resistance to etching solutions. Thus, when a conductive layer on the channel layer is patterned to form a source electrode and a drain electrode, the channel is less susceptible to damage from the etching solution, so thin-film transistors can be fabricated with high quality and low cost.

To make the above characteristics and advantages of the present disclosure more clear and easier to understand, the following embodiments are described in detail in conjunction with accompanying figures.

### BRIEF DESCRIPTIONS OF THE DRAWINGS

FIG. 1A to FIG. 1E are schematic views of a method of fabricating a thin film transistor in accordance with an embodiment of the present disclosure.

FIG. 2 is a TEM diffraction image of a crystalline indium-gallium-zinc oxide semiconductor layer in accordance with FIG. 1B.

FIG. 3 is a TEM diffraction image of a conventional indium-gallium-zinc oxide semiconductor layer.

FIG. 4 is an X-ray diffraction graph of a crystalline indium-gallium-zinc oxide semiconductor layer in accordance with FIG. 1B.

FIG. 5 is an X-ray diffraction graph of a conventional indium-gallium-zinc oxide semiconductor layer.

FIG. 6A to FIG. 6E are schematic views of a method of fabricating a thin film transistor in accordance with another embodiment of the present disclosure.

### DETAILED DESCRIPTIONS

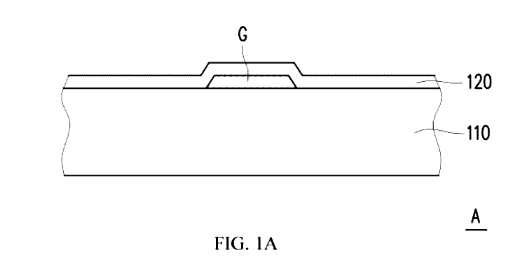

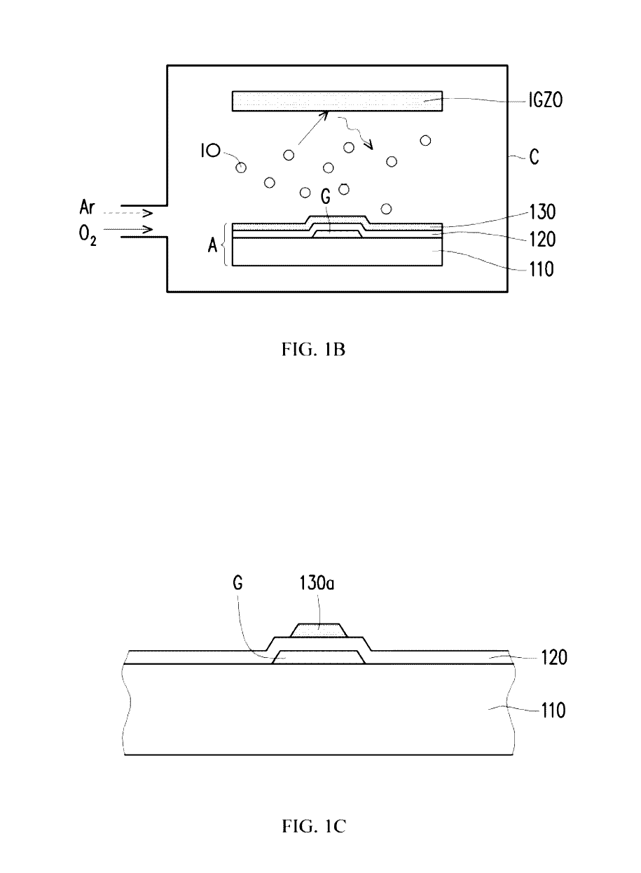

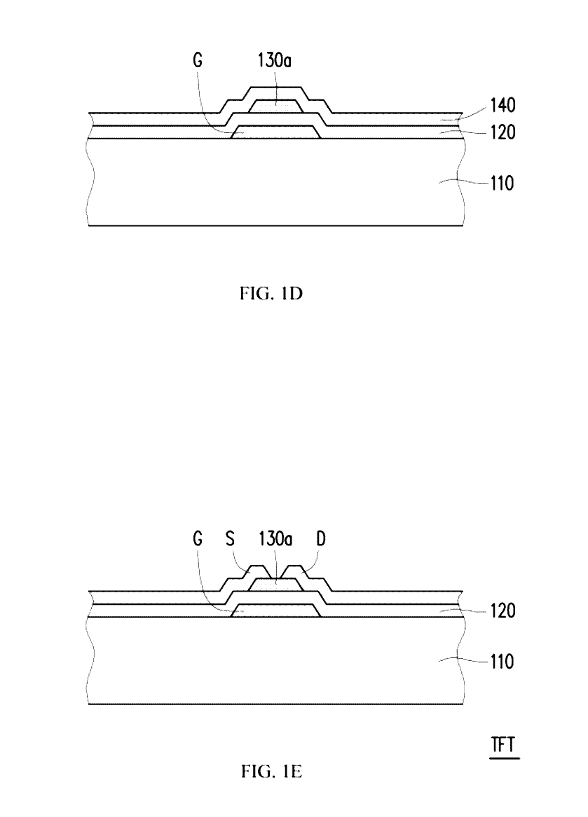

FIG. 1A to FIG. 1E are schematic views of a method of fabricating a thin film transistor in accordance with an embodiment of the present disclosure. Please refer to FIG. 1A. First, a substrate 110 is provided. The substrate 110 may be a light-transmissive substrate, an opaque/reflecting substrate, or a flexible substrate. A material of the light-transmissive substrate, for example, may be glass, quartz, or other suitable materials. A material of the opaque/reflecting substrate may be conductive material, wafer, ceramic, or other suitable materials. A material of the flexible substrate may be Polyimide (PI), Polyethylene Naphthalate (PEN), Polyethersulfone (PES), or other suitable materials. Next, a gate electrode G is formed on the substrate 110. In the present embodiment, the gate electrode G is, for example, made of metallic material, and the present disclosure is not limited thereto. In other embodiments, the gate electrode G may be made of other conductive materials (such as alloy, metal nitrides, metal oxides, nitrogen metal oxynitrides, or stacked layers of metals and other conductive materials). Then, an insulating layer 120 is formed on the substrate 110 to cover the gate electrode G. A material of the insulating layer 120 may be an inorganic material (such as silicon oxide, silicon nitride, silicon oxynitride, or a stacked layer of at least two of the above-mentioned materials), an organic material, or the combination thereof. The substrate 110, the gate electrode G, and the insulating layer 120 may be referred to as a matrix A. Next, optionally, the matrix A is cleaned to remove the impurities on the matrix A, and the present disclosure is not limited thereto.

Next refer to FIG. 1B, the matrix A is placed into a chamber C of a sputter. Further, the matrix A is heated to over 200 Celsius degrees(° C.) before an indium-gallium-zinc oxide sputter target IGZO is bombarded with plasma-generated ions. Next, a crystalline indium-gallium-zinc oxide semiconductor layer 130 is formed on the matrix A by bombarding the indium-gallium-zinc oxide sputter target IGZO with the plasma-generated ions IO in a condition of a process temperature higher than 200 Celsius degrees, an oxygen gas O₂ flow greater than 60 sccm (standard cubic centimeter per minute), and an argon gas Ar flow less than 20 sccm. In other words, in the present embodiment, oxygen is primarily used as the gas for generating the plasma, along with a high process temperature (to over 200° C.), so that the IGZO molecules on the indium-gallium-zinc oxide sputter target IGZO are provided with sufficient energy. Thereby, a “crystalline” indium-gallium-zinc oxide semiconductor layer 130 is deposited on the matrix A.

In the present embodiment, the process temperature is from 200° C. to 270° C., the argon gas Ar flow is less than 5 sccm, and the oxygen gas O₂ flow is less than 100 sccm while bombarding the indium-gallium-zinc oxide sputter target IGZO with the plasma-generated ions IO. Nevertheless, the present disclosure is not limited thereto, and in other embodiments, the process temperature, the argon gas flow, and the oxygen gas flow may be within other suitable ranges.

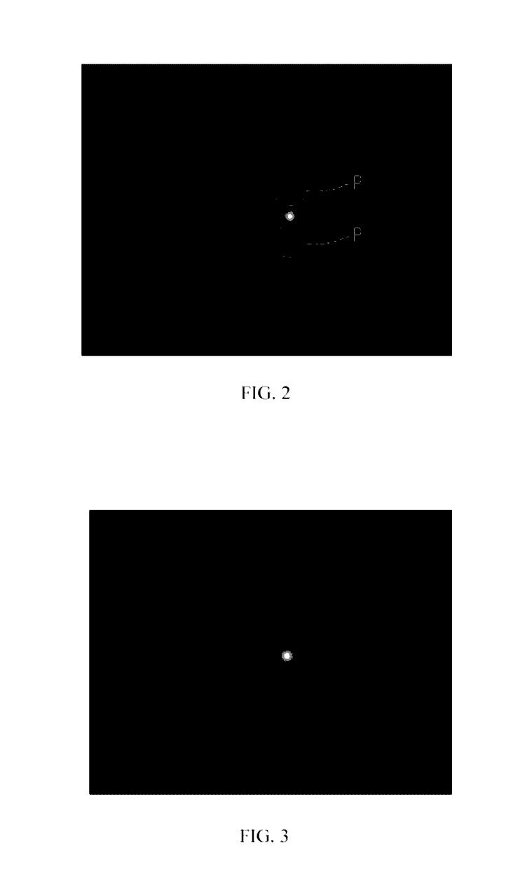

FIG. 2 is a Transmission Electron Microscopy (TEM) diffraction image of a crystalline indium-gallium-zinc oxide semiconductor layer 130 in accordance with FIG. 1B. FIG. 3 is a TEM diffraction image of a conventional indium-gallium-zinc oxide semiconductor layer. The difference between the fabrication processes of the conventional indium-gallium-zinc oxide semiconductor layer and that of the crystalline indium-gallium-zinc oxide semiconductor layer 130 is the conventional indium-gallium-zinc oxide semiconductor layer is formed by bombarding the indium-gallium-zinc oxide sputter target IGZO with plasma-generated ions in a condition of an oxygen gas flow of almost 0 sccm and an argon gas Ar flow of 145 sccm. Comparing FIG. 2 with FIG. 3, it is shown that the TEM diffraction image of the crystalline indium-gallium-zinc oxide semiconductor layer 130 of the present embodiment has significant constructive speckles P, and the TEM diffraction image of the conventional indium-gallium-zinc oxide semiconductor layer has no significant constructive speckle. In other words, FIG. 2 can be a proof of that, the crystalline indium-gallium-zinc oxide semiconductor layer 130 with good crystallization quality can certainly be formed on the matrix A by bombarding the indium-gallium-zinc oxide sputter target IGZO with the plasma-generated ions IO in a condition of a process temperature higher than 200° C., an oxygen gas O₂ flow greater than 60 sccm, and an argon gas Ar flow less than 20 sccm.

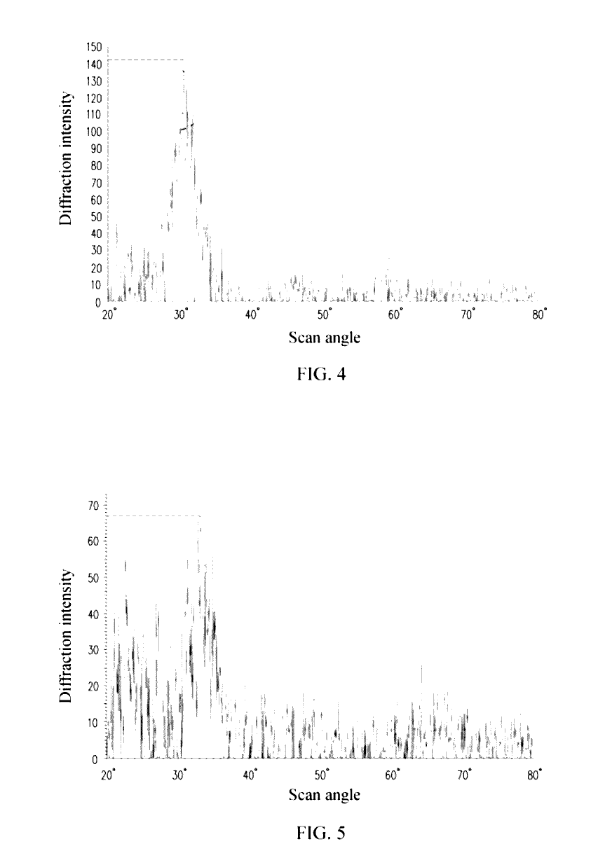

FIG. 4 is an X-ray diffraction (XRD) graph of a crystalline indium-gallium-zinc oxide semiconductor layer in accordance with FIG. 1B. FIG. 5 is an X-ray diffraction graph of a conventional indium-gallium-zinc oxide semiconductor layer. Comparing FIG. 4 with FIG. 5, it is shown that, the diffraction intensity in a scan angle ranging from 30 to 40 degrees in the X-ray diffraction graph of the crystalline indium-gallium-zinc oxide semiconductor layer 130 (about 140 intensity units) is much higher than the diffraction intensity of the conventional indium-gallium-zinc oxide semiconductor layer (about 67 intensity units). In other words, FIG. 4 can be a proof of that, the crystalline indium-gallium-zinc oxide semiconductor layer 130 with good crystallization quality can certainly be formed on the matrix A by bombarding the indium-gallium-zinc oxide sputter target IGZO with the plasma-generated ions IO in a condition of a process temperature higher than 200° C., an oxygen gas O₂ flow greater than 60 sccm, and an argon gas Ar flow less than 20 sccm.

Refer to FIG. 1B and FIG. 1C. After the matrix A and the crystalline indium-gallium-zinc oxide semiconductor layer 130 on the matrix A are taken out of the chamber C of the sputter, the crystalline indium-gallium-zinc oxide semiconductor layer 130 is patterned, such that part of the crystalline indium-gallium-zinc oxide semiconductor layer 130 is remained on the substrate 110. The part of the crystalline indium-gallium-zinc oxide semiconductor layer 130 remained on the substrate 110 may be used as a channel layer 130a of a thin film transistor. The channel layer 130a overlaps the gate electrode. Refer to FIG. 1D, a conductive layer 140 is formed on the substrate 110 to cover the channel layer 130a. In the present embodiment, the conductive layer 140 is, for example, made of metallic material, and the present disclosure is not limited thereto. In other embodiments, the conductive layer 140 may be made of other conductive materials (such as alloy, metal nitrides, metal oxides, nitrogen metal oxynitrides, or stacked layers of metals and other conductive materials). Refer to FIG. 1D and FIG. 1E, the conductive layer 140 is patterned to form a source electrode S and a drain electrode D, where the source electrode S and the drain electrode D are separated from each other and are directly contacted with and electrically connected to two ends of the channel layer 130a. Thus, a thin film transistor TFT of the present embodiment is completed.

For example, in the present embodiment, the conductive layer 140 may be patterned by using a wet etching process to form the source S electrode and the drain electrode D. It is worth mentioning that, due to the fact that the channel layer 130a is made of the crystalline indium-gallium-zinc oxide semiconductor layer 130, the channel layer 130a has the ability of anti-etching solution. Accordingly, when the conductive layer 140 is patterned by a wet etching process to form the source electrode S and the drain electrode D, the crystalline structure of the channel layer 130a can resist the corrosion of etching solution used in the wet etching process, such that the channel layer 130a is not easily damaged. For example, when the material of the patterned conductive layer 140 is composed of molybdenum, aluminum and molybdenum, the aluminum acid is used in performing a wet etching process to form the source electrode S and the drain electrode D, and the crystalline structure of the channel layer 130a can resist the corrosion of the aluminum acid, preventing the channel layer 130a from being damaged. In other words, the method of fabricating a thin film transistor of the present embodiment may utilize a wet etching process with short process time and low cost for patterning as to form the source electrode S and drain electrode D with perfect quality of the channel layer 130a, and thus the thin film transistor TFT is fabricated with good quality and low cost.

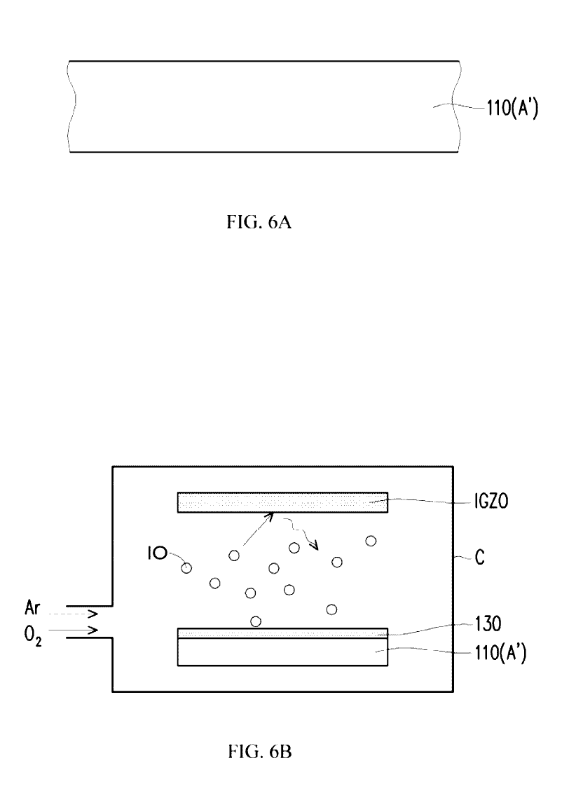

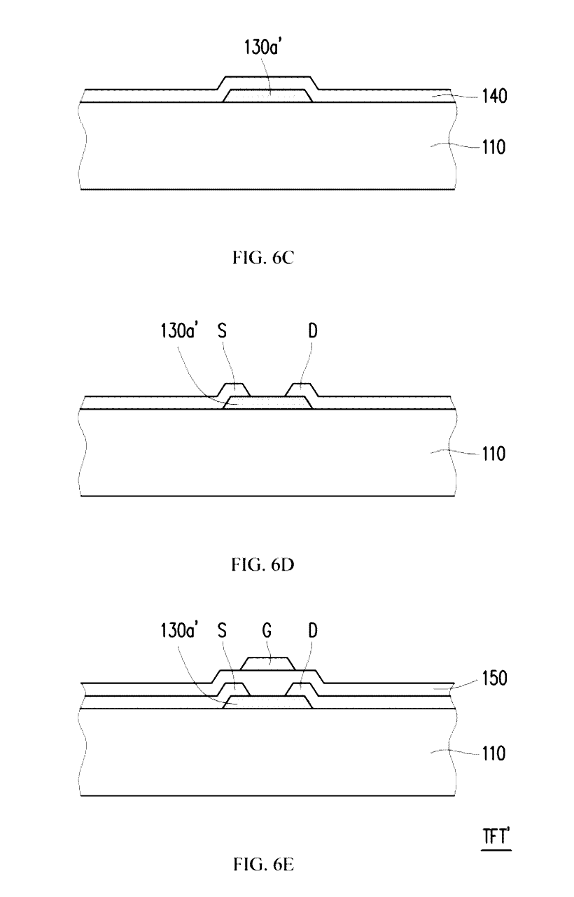

As shown in FIG. 1E, in the present embodiment, the gate electrode G is located below the channel layer 130a. In other words, the thin film transistor TFT of the present embodiment may be a bottom gate thin film transistor (bottom gate TFT). Nevertheless, the methods of fabricating a crystalline indium-gallium-zinc oxide semiconductor layer and fabricating a thin film transistor of the present disclosure are not limited to the application of fabricating a bottom gate thin film transistor, and the methods of fabricating a crystalline indium-gallium-zinc oxide semiconductor layer and fabricating a thin film transistor of the present disclosure may also be used to fabricate thin film transistors of other types or other semiconductor components, which are described in the following in conjunction with FIG. 6A to FIG. 6E.

FIG. 6A to FIG. 6E are schematic views of a method of fabricating a thin film transistor in accordance with another embodiment of the present disclosure. The method of fabricating a thin film transistor in FIG. 6A to FIG. 6E is similar to the method of fabricating a thin film transistor in FIG. 1A to FIG. 1E, therefore the same or corresponding elements are referred by the same or corresponding numerals. The difference between the method of fabricating a thin film transistor in FIG. 6A to FIG. 6E and the method of fabricating a thin film transistor in FIG. 1A to FIG. 1E is the gate electrode G are formed at different time. The difference will be described more specifically in the following, and the features believed to be the same will be understood by referring to the above detailed description in conjunction with the numerals in FIG. 6A to FIG. 6E, and thus will not be repeated herein.

Refer to FIG. 6A, at first, a substrate 110 is provided, and the substrate 100 may be regarded as a matrix A′. Next refer to FIG. 6B, the matrix A′ is placed into a chamber C of the sputter. Further, the matrix A′ is heated to over 200° C. before an indium-gallium-zinc oxide sputter target IGZO is bombarded with plasma-generated ions. Next, a crystalline indium-gallium-zinc oxide semiconductor layer 130 is formed on the matrix A′ by bombarding the indium-gallium-zinc oxide sputter target IGZO with the plasma-generated ions IO in a condition of a process temperature higher than 200° C., an oxygen gas O₂ flow greater than 60 sccm, and an argon gas Ar flow less than 20 sccm.

Refer to FIG. 6B and FIG. 6C, after the matrix A′ and the crystalline indium-gallium-zinc oxide semiconductor layer 130 on the matrix A′ are taken out of the chamber C of the sputter, the crystalline indium-gallium-zinc oxide semiconductor layer 130 is patterned, such that part of the crystalline indium-gallium-zinc oxide semiconductor layer 130 is remained on the substrate 110. The part of the crystalline indium-gallium-zinc oxide semiconductor layer 130 remained on the substrate 110 may be used as a channel layer 130a′ of a thin film transistor. Next refer to FIG. 6C, a conductive layer 140 is formed on the substrate 110 to cover the channel layer 130a′. Next refer to FIG. 6C and FIG. 6D, the conductive layer 140 is patterned to form a source electrode S and a drain electrode D, where the source electrode S and the drain electrode D are separated from each other and are directly contacted with and electrically connected to two ends of the channel layer 130a′. Next refer to FIG. 6E, an insulating layer 150 is formed on the substrate 110 to cover the source electrode S and the drain electrode D. A material of the insulating layer 150 may be an inorganic material (such as silicon oxide, silicon nitride, silicon oxynitride, or a stacked layer of at least two of the above-mentioned materials), an organic material, or the combination thereof. Then, a gate electrode G overlapping the channel layer 130a′ is formed on the insulating layer 150. Thus, a thin film transistor TFT′ of the present embodiment is completed.

As shown in FIG. 6E, in the present embodiment, the gate electrode G is located on the channel layer 130a′. In the present embodiment, the thin film transistor may be a top gate thin film transistor (top gate TFT). Nevertheless, it should be noted that, the methods of fabricating a crystalline indium-gallium-zinc oxide semiconductor layer and fabricating a thin film transistor of the present disclosure are not limited to the application of fabricating a top gate and a bottom gate thin film transistors as above described, and the methods of fabricating a crystalline indium-gallium-zinc oxide semiconductor layer and fabricating a thin film transistor of the present disclosure may also be used to fabricate thin film transistors of other types (such as a dual-gate thin film transistor and the like) or other semiconductor components. Those skilled in the art may utilize the methods of fabricating a crystalline indium-gallium-zinc oxide semiconductor layer and fabricating a thin film transistor of the present disclosure according to the above detailed description to implement thin film transistors of other types or other semiconductor components, and the details will not be repeated herein.

In summary, in the method of fabricating a crystalline indium-gallium-zinc oxide semiconductor layer in accordance with an embodiment of the present disclosure, a crystalline indium-gallium-zinc oxide semiconductor layer is formed by bombarding an indium-gallium-zinc oxide sputter target with plasma-generated ions in a condition of a process temperature higher than 200° C., an oxygen gas flow greater than 60 sccm, and an argon gas flow less than 20 sccm. Thereby, the crystalline indium-gallium-zinc oxide semiconductor layer has a good crystallization quality and the ability of anti-etching solution.

In the method of fabricating a thin film transistor in accordance with an embodiment of the present disclosure, a channel layer of the fabricated thin film transistor is formed by patterning the above-mentioned crystalline indium-gallium-zinc oxide semiconductor layer, therefore, the channel layer also has the ability of anti-etching solution. Thus, when a conductive layer on the channel layer is patterned to form a source electrode and a drain electrode, the channel layer is not easily damaged from the etching solution, so thin-film transistors can be fabricated with high quality and low cost.

Even though the present disclosure has been disclosed as the above-mentioned embodiments, it is not limited thereto. Any of those skilled in the art may make some changes and adjustments without departing from the spirit and scope of the present disclosure. Therefore, the scope of the present disclosure is defined in view of the appended claims.

What is claimed is:

1. A method of fabricating a crystalline indium-gallium-zinc oxide semiconductor layer, comprising:
forming a crystalline indium-gallium-zinc oxide semiconductor layer on a substrate by bombarding an indium-gallium-zinc oxide sputter target with plasma-generated ions in a condition of a process temperature higher than 200 Celsius degrees, an oxygen gas flow greater than 60 sccm, and an argon gas flow less than 20 sccm.

2. The method of fabricating a crystalline indium-gallium-zinc oxide semiconductor layer of claim 1, further comprising:
heating the substrate to over 200 Celsius degrees before bombarding the indium-gallium-zinc oxide sputter target with the plasma-generated ions.

3. The method of fabricating a crystalline indium-gallium-zinc oxide semiconductor layer of claim 1, wherein the process temperature is from 200 to 270 Celsius degrees while bombarding the indium-gallium-zinc oxide sputter target with the plasma-generated ions.

4. The method of fabricating a crystalline indium-gallium-zinc oxide semiconductor layer of claim 1, wherein the argon gas flow is less than 5 sccm and the oxygen gas flow is less than 100 sccm while bombarding the indium-gallium-zinc oxide sputter target with the plasma-generated ions.

5. A method of fabricating a thin film transistor, comprising:
forming a gate electrode, a source electrode, a drain electrode, and a crystalline indium-gallium-zinc oxide semiconductor layer on a substrate, wherein the crystalline indium-gallium-zinc oxide semiconductor layer is formed by bombarding an indium-gallium-zinc oxide sputter target with plasma-generated ions in a condition of a process temperature higher than 200 Celsius degrees, an oxygen gas flow greater than 60 sccm, and an argon gas flow less than 20 sccm.

6. The method of fabricating a thin film transistor of claim 5, further comprising:
heating the substrate to over 200 Celsius degrees before bombarding the indium-gallium-zinc oxide sputter target with the plasma-generated ions.

7. The method of fabricating a thin film transistor of claim 6, wherein the process temperature is from 200 to 270 Celsius degrees while bombarding the indium-gallium-zinc oxide sputter target with the plasma-generated ions.

8. The method of fabricating a thin film transistor of claim 6, wherein the argon gas flow is less than 5 sccm and the oxygen gas flow is less than 100 sccm while bombarding the indium-gallium-zinc oxide sputter target with the plasma-generated ions.

9. A thin film transistor fabricated by the method of fabricating a thin film transistor of claim 5, the thin film transistor comprising:
the gate electrode;
the crystalline indium-gallium-zinc oxide semiconductor layer overlapping the gate; and
the source electrode and the drain electrode, partially overlapping and electrically connected to two ends of the crystalline indium-gallium-zinc oxide semiconductor layer respectively.
